(19) United States
(12) Patent Application Publication
(10) Pub. No.: US 2005/0000430 A1
(43) Pub. Date: Jan. 6, 2005

(54) Showerhead assembly and apparatus for manufacturing semiconductor device having the same

(76) Inventors: Geun-Ha Jang, Gyeonggi-do (KR); Chi-Wook Yu, Gyeonggi-do (KR)

Correspondence Address: MARGER JOHNSON & McCOLLOM, P.C., 1030 S.W. Morrison Street, Portland, OR, 97205, US

(21) Appl. No.: 10/852,929

(22) Filed: May 24, 2004

(30) Foreign Application Priority Data
May 22, 2003 (KR) 2003-32452

(51) Int. Cl. C23C 16/00

(52) U.S. Cl. 118/715

(57) ABSTRACT

A showerhead assembly of an apparatus for manufacturing a semiconductor device includes a backing plate having a gas inlet, a showerhead combined with the backing plate at an end portion thereof, wherein the showerhead has a plurality of holes, and a sub heater equipped at a peripheral portion of the showerhead.

This application claims the benefit of Korean Patent Application No. 2003-0032452, filed on May 22, 2002, which is hereby incorporated by reference for all purposes as if fully set forth herein.

### BACKGROUND OF THE INVENTION

1. Field of the Invention

The present invention relates to an apparatus for manufacturing a semiconductor device, and more particularly, to a showerhead assembly and the apparatus for manufacturing the semiconductor device having the same.

2. Discussion of the Related Art

A liquid crystal display (LCD) device includes an array substrate, a color filter substrate, and a liquid crystal layer interposed therebetween, and transmits light by using optical properties of the liquid crystal layer to thereby display images.

The array substrate and the color filter substrate are manufactured by repeatedly depositing a thin film on a transparent substrate, such as a glass substrate, and then patterning the thin film through a photolithography process. The thin film may be deposited or etched by supplying reaction and source materials of a gas phase through a downstream method from an upper portion of a processing chamber, and a showerhead assembly is disposed over the substrate to uniformly distribute the reaction and source gases on an upper surface of the substrate. The showerhead assembly includes a showerhead having a plurality of through holes.

Recently, a plasma enhanced chemical vapor deposition (PECVD) method is widely used to deposit the thin film. The PECVD method excites processing gases using high voltage to form plasma, and thus enhances chemical reactions between processing gases.

A depositing apparatus of a thin film for the PECVD method will be described hereinafter with reference to attached drawings.

FIG. 1 is a view schematically illustrating a related art PECVD apparatus, and FIG. 2 is a view magnifying the part “A” of FIG. 1. As shown in FIGS. 1 and 2, the PECVD apparatus includes a processing chamber 10, which is isolated from the outside to form a reaction space. The processing chamber 10 includes an upper cover 12 and a chamber body 14. An O-ring 16 is interposed between the upper cover 12 and the chamber body 14 to make the inside of the processing chamber 10 airtight from the outside.

The upper cover 12 is isolated from the outside by a lid 22, and in the lid 22, a backing plate 34 and a showerhead 30 are equipped across the inside thereof.

Processing gases go through a gas line (not shown) from a gas supplier (not shown) of the outside, and then are injected into a space under the backing plate 34 through a gas inlet 70, which passes through the center of the backing plate 34. The injected processing gases are first diffused by a baffle (not shown) under the backing plate 34, and under the baffle and the backing plate 34, are uniformly sprayed toward an upper surface of a substrate S disposed on a susceptor 60 through a plurality of through holes 32 of the showerhead 30.

A radio frequency (RF) power source 80, which supplies energy for exciting the injected processing gases, is connected to the backing plate 34 and the showerhead 30, and the injected processing gases through the showerhead 30 are activated, whereby a thin film is deposited. Thus, the backing plate 34 and the showerhead 30 serve as an upper electrode.

Sides of the chamber body 14 are combined with the lid 22 of the upper cover 12, and as stated above, the O-ring 16 is interposed the chamber body 14 and the lid 22 of the upper cover 12. The susceptor 60 is disposed in the chamber body 14. The susceptor 60 is spaced apart from and facing the showerhead 30, and the substrate S is located on the upper surface of the susceptor 60. A heater 62 is laid in the susceptor 60, and heats the substrate S on the susceptor 60 to appropriate temperatures for deposition during a depositing process. In addition, the susceptor 60 is grounded and serves as a lower electrode. To prevent the processing materials from being deposited on edges of the substrate S, edge frames 64 are equipped on the upper surface of the susceptor 60 and cover the edges of the substrate S.

An outlet 52 is formed at a lower side of the chamber body 14 under the susceptor 60 so that the processing gases are exhausted to the outside when the depositing process is completed.

The showerhead 30 and the backing plate 34, which spray the processing gases onto the upper surface of the substrate S and function as the upper electrode, are combined by bolts 42 at edges thereof and are electrically connected to each other. A plurality of insulators 44, 46 and 48 are interposed between peripheral portions, where the showerhead 30 and the backing plate 34 are combined, and a side lid 20 to electrically insulate the showerhead 30 and the backing plate 34 from the side lid 20 and keep the inside of the processing chamber vacuum. O-rings 49 are inserted between the insulator 48 and the backing plate 34 and between the insulator 48 and the lid 20.

In the related art PEVCE apparatus, to deposit a thin film on the upper surface of the substrate by thermal decomposition of the processing gases, the susceptor 60 is maintained under the temperature of about 300 to 400 degrees of Celsius due to operation of the heater 62. Therefore, although the showerhead 30 is spaced apart from the susceptor 60 with a space of about 10 to 30 cm, the temperature of the showerhead 30 also rises.

However, since outer walls of the processing chamber 10 take heat away from the peripheral portions of the showerhead 30, the peripheral portions and the center portion of the showerhead 30 do not have the same temperature to be thermally out of balance. That is, the peripheral portions of the showerhead 30 have the lower temperature than the center portion of the showerhead 30 owing to thermal loss of the peripheral portions of the showerhead 30. Thus, in the peripheral portions of the showerhead 30, because the processing gases do not react according to the thermal decomposition, the processing gases remain as a powder form, which results in particles.

Especially, the peripheral portions of the showerhead 30 contact a lower surface of the backing plate 34 through an upper surface thereof, and as shown in FIG. 2, the peripheral portions of the showerhead 30 are combined with the backing plate with the same thickness as other portions, i.e., the center portion. Therefore, heat transmitted from the susceptor 60 to the peripheral portions of the showerhead 30 is conducted to the backing plate 34, and thus more thermal loss occurs in the peripheral portions as compared with the center portion.

In this case, the insulator 48 and the O-ring 49 may be damaged and may not function, wherein the insulator 48 is inserted between the backing plate 34 and the lid 22 to electrically isolate the backing plate 34 and the lid 22, and the O-ring 49 is disposed on and beneath the insulator 48 to maintain the vacuum condition in the processing chamber 10. The insulator 48 may be made of PTFE (Polytetrafluoroethylene).

Since there is thermally out of balance depending on portions, in the peripheral portions of the showerhead 30 having the lower temperature than the center portion, the processing gases injected from the outside are not thermally decomposed completely, and have powder forms, which result in particles. This contaminates the inside of the processing chamber 10. Therefore, a cleaning cycle of the processing chamber 10 increases and thus productivity of the manufacturing process decreases.

To prevent the temperature of the backing plate 34 from rising due to the thermal conduction from the showerhead 30, the inner part of the backing plate 34 may be connected to a heat exchanger of the outside to decrease the temperature of the backing plate 34.

However, the manufacturing costs are increased and complexity in controlling the apparatus is caused. Moreover, RF power transported to the upper electrode, that is, the backing plate 34 and the showerhead 30, through a medium, may be lost, and thus the plasma may be changed to have a bad effect on fabricated devices.

In addition, as the temperature of the backing plate 34 falls, the peripheral portions of the showerhead 30, which contacts the backing plate 34, also have decreasing temperatures. The processing gases still do not react and have the powder forms. Accordingly, particles are generated, and devices of bad qualities are produced because the susceptor 60 facing the showerhead 30 has non-uniform temperatures.

Meanwhile, the showerhead 30 is generally made of aluminum and the showerhead 30 is easily expanded due to heat radiated from the susceptor 60 and the substrate S on the susceptor 60. The showerhead 30 has an increased size according as the substrate, recently, has a large size, and the large showerhead 30 is more expanded according to the rising temperature.

As stated above, there are differences in thermal expansion between the peripheral portions and the center portion of the showerhead 30 because of different temperatures depending on portions, and the coefficient of thermal expansion in the center portion is larger than the coefficient of thermal expansion in the peripheral portions. Thus, a thermal transformation rate of the showerhead 30 varies and the showerhead 30 may be distorted and twisted.

Since the peripheral portions of the showerhead 30 is combined with the backing plate 34 through the bolts 42 and the expansion of the peripheral portions is suppressed, the showerhead 30 is more distorted because of different thermal expansion rates depending on portions. Therefore, distances between the lower surface of the showerhead 30, which functions as the upper electrode, and the substrate S, which is disposed on the upper surface of the susceptor 60, are not uniform at every portion, and deposition rates of the processing materials on the substrate S, also, are not equal.

Finally, deterioration of a deposited film and generation of particles, which are caused by transformation of the peripheral portions due to the limited thermal expansion and by different temperatures of the showerhead 30 depending on portions and resulting from thermal conduction to the backing plate 34, are left as problems to be essentially solved.

### SUMMARY OF THE INVENTION

Accordingly, the present invention is directed to a showerhead assembly and the apparatus for manufacturing the semiconductor device having the same that substantially obviates one or more of problems due to limitations and disadvantages of the related art.

An advantage of the present invention is to provide a showerhead assembly and the apparatus for manufacturing the semiconductor device having the same that minimizes thermal expansion-induced deformation and forms a thin film of uniform properties.

Another advantage is to provide a showerhead assembly and the apparatus for manufacturing the semiconductor device having the same that compensates thermal unbalance due to thermal loss in a peripheral portion of the showerhead.

Another advantage is to provide a showerhead assembly and the apparatus for manufacturing the semiconductor device having the same that minimizes thermal conduction from the showerhead to backing plate.

Another advantage is to provide a showerhead assembly and the apparatus for manufacturing the semiconductor device having the same that suppresses formation of powder and particles in the peripheral portion of the showerhead to improve productivity.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, a showerhead assembly of an apparatus for manufacturing a semiconductor device includes a backing plate having a gas inlet, a showerhead combined with the backing plate at an end portion thereof, wherein the showerhead has a plurality of holes, and a sub heater equipped at a peripheral portion of the showerhead.

In another aspect, an apparatus for manufacturing a semiconductor device includes a chamber, a susceptor in the chamber to hold a substrate thereon, a showerhead assembly providing gas to the chamber, wherein the showerhead assembly includes a backing plate having a gas inlet, a showerhead combined with the backing plate at an end portion thereof, the showerhead having a plurality of holes and a sub heater equipped at a peripheral portion of the showerhead, and a pumping system controlling inner pressure of the chamber.

It is to be understood that both the foregoing general description and the following detailed description are exemplary and explanatory and are intended to provide further explanation of the invention as claimed.

### BRIEF DESCRIPTION OF THE DRAWING

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a view schematically illustrating a related art PECVD apparatus.

FIG. 2 is a view magnifying the part “A” of FIG. 1.

FIG. 3 is a view schematically showing a PECVD apparatus for manufacturing the semiconductor device according to a first embodiment of the present invention.

FIG. 4 is a view magnifying the part “B” of FIG. 3.

FIG. 5 is a cross-sectional view illustrating an expanded showerhead due to heat conducted from a susceptor according to the first embodiment of the present invention.

FIG. 6 is a cross-sectional view schematically illustrating a PECVD apparatus according to a second embodiment of the present invention,

FIG. 7 is a view magnifying the part “B” of FIG. 6.

FIG. 8A is a view vertically cutting the sub heater of the present invention, and FIG. 8B is a cross-sectional view along the line VIII-VIII of FIG. 8A.

FIGS. 9A to 9D are views showing a process inserting a sub heater into an upper surface of the showerhead according to the present invention.

FIG. 10 is a view illustrating a part of a showerhead assembly according to a third embodiment of the present invention.

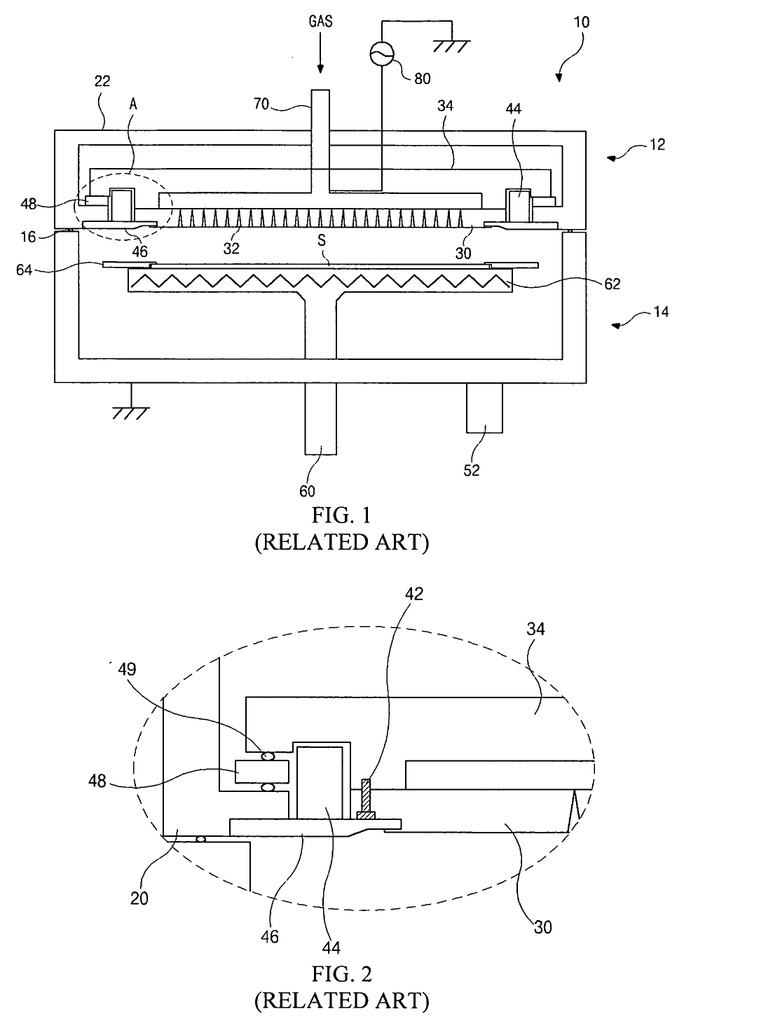

### DETAILED DESCRIPTION OF THE ILLUSTRATED EMBODIMENTS

Reference will now be made in detail to the illustrated embodiments of the present invention, which are illustrated in the accompanying drawings. Wherever possible, the same reference numbers will be used throughout the drawings to refer to the same or like parts.

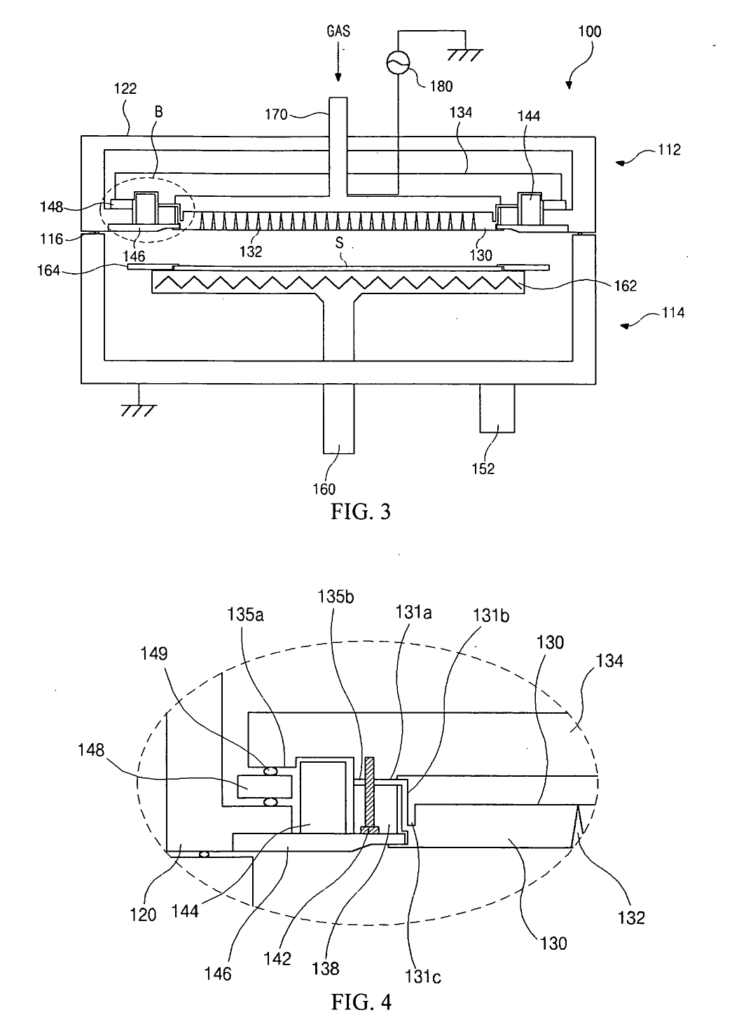

FIG. 3 is a view schematically showing a PECVD apparatus for manufacturing the semiconductor device according to a first embodiment of the present invention, and is to deposit a thin film, for example.

In the apparatus of FIG. 3, a deposition process of a thin film is carried out in a processing chamber 100, which is isolated from the outside and forms a reaction space of a vacuum condition therein. The processing chamber 100 includes an upper cover 112 and a chamber body 114. A sealing material 116 such as an O-ring is interposed between the upper cover 112 and the chamber body 114 to make the inside of the processing chamber 100 airtight from the outside.

The upper cover 112 is isolated from the outside by a lid 122, and in the lid 122, a backing plate 134 and a showerhead 130 are equipped across the inside thereof.

Processing gases go through a gas line (not shown) from a gas supplier (not shown) of the outside, and then are injected into a space under the backing plate 134 through a gas inlet 170, which passes through the center of the backing plate 134. The injected processing gases are first diffused by a baffle (not shown) under the backing plate 134, and are uniformly sprayed toward an upper surface of a substrate S disposed on a susceptor 160 through a plurality of through holes 132 of the showerhead 130.

A radio frequency (RF) power source 180, which supplies energy for exciting the injected processing gases, is connected to the backing plate 134 and the showerhead 130, and plasma is generated by activating the injected processing gases through the showerhead 130, whereby a thin film is deposited. Thus, the backing plate 134 and the showerhead 130 serve as an upper electrode.

Sides of the chamber body 114 are combined with the lid 122 of the upper cover 112, and as stated above, the sealing material 116 is interposed the chamber body 114 and the lid 122 of the upper cover 112. The susceptor 160 is disposed in the chamber body 114. The susceptor 160 is spaced apart from and facing the showerhead 130, and the substrate S is located on the upper surface of the susceptor 160. A heater 162 is laid in the susceptor 160, and heats the substrate S on the susceptor 160 to appropriate temperatures for deposition during a depositing process. In addition, the susceptor 160 is grounded and serves as a lower electrode. To prevent the processing materials from being deposited on edges of the substrate S and at sidewalls of the processing chamber 100 and to adhere the substrate S closely to the susceptor 160, edge frames 164 are equipped on the upper surface of the susceptor 160 and on sides of the substrate S, and cover the edges of the substrate S.

A lifting means (not shown) is connected to a lower part of the susceptor 160 and moves the susceptor 160 up and down according to loading and unloading of the substrate S in and out the processing chamber 100.

An outlet 152 is formed at a lower side of the chamber body 114 under the susceptor 160 so that the processing gases are exhausted to the outside when the depositing process is completed.

FIG. 4 is a view magnifying the part “B” of FIG. 3, and shows a peripheral portion of a showerhead assembly according to the first embodiment.

In FIG. 4, an end portion 131a of the showerhead 130, which is combined with a connecting part 135b of the backing plate 134, has a sheet shape, that is, a horizontally thin and long shape, as compared with a center portion of the showerhead 130 having the plurality of through holes 132. Therefore, in the end portion 131a, a lower surface of the showerhead 130 is close by an upper surface thereof. Although the end portion 131a of the showerhead 130 is higher than the center portion of the showerhead 130, the position of the end portion 131a may be changed.

If the end portion 131a of the showerhead 130 has the thin and long shape, the end portion 131a of the showerhead 130 and the connecting part 135b of the backing plate 134 may be unstably combined. To stably combine the showerhead 130 and the backing plate 134, a clamping bar 138 is equipped under the end portion 131a of the showerhead 130, and supports the end portion 131a of the showerhead 130.

The connecting part 135b of the backing plate 134, the end portion 131a of the showerhead 130 and the clamping bar 138 are combined by a connecting means 142 such as a bolt and are electrically connected.

Beneficially, a concavity 131c is formed at the upper surface of the showerhead 130 inside the end portion 131a of the showerhead 130 that is combined with the connecting part 135b of the backing plate 134. Then, a vertical portion 131b is formed between the end portion 131a of the showerhead 130 and the concavity 131c, and connects the end portion 131a of the showerhead 130 and the concavity 131c.

The vertical portion 131b is spaced apart from the champing bar 138 so that the concavity 131c is expanded to the outside.

A plurality of insulators 144, 146 and 148 are interposed between peripheral portions, where the showerhead 130 and the backing plate 134 are combined, and a side lid 120 to electrically insulate the showerhead 130 and the backing plate 134 from the side lid 120 and keep the inside of the processing chamber 100 vacuum. For example, to prevent generation of plasma between the side lid 120 and the upper electrode (that is, the showerhead 130 and the backing plate 134), a ceramic insulator 144 is formed outside the connecting part 135b of the backing plate 134, the end portion 131a of the showerhead 130, and the clamping bar 138, and electrically isolates the upper electrode from the side lid 120. A ceramic expansion part 146 is disposed along lower surfaces of the clamping bar 138 under the end portion 131a and the ceramic insulator 144 and passes through a part of a lower surface of the side lid 120. A PTFE (Polytetrafluoroethylene) insulator 148 is disposed between an end part 135a of the backing plate 134 and the side lid 120, and electrically isolates the end part 135a of the backing plate 134 and the side lid 120. O-rings 149 are inserted between the PTFE insulator 148 and the end part 135a of the backing plate 134 and between the PTFE insulator 148 and the side lid 120 to keep the vacuum condition of the processing chamber 100 from the outside.

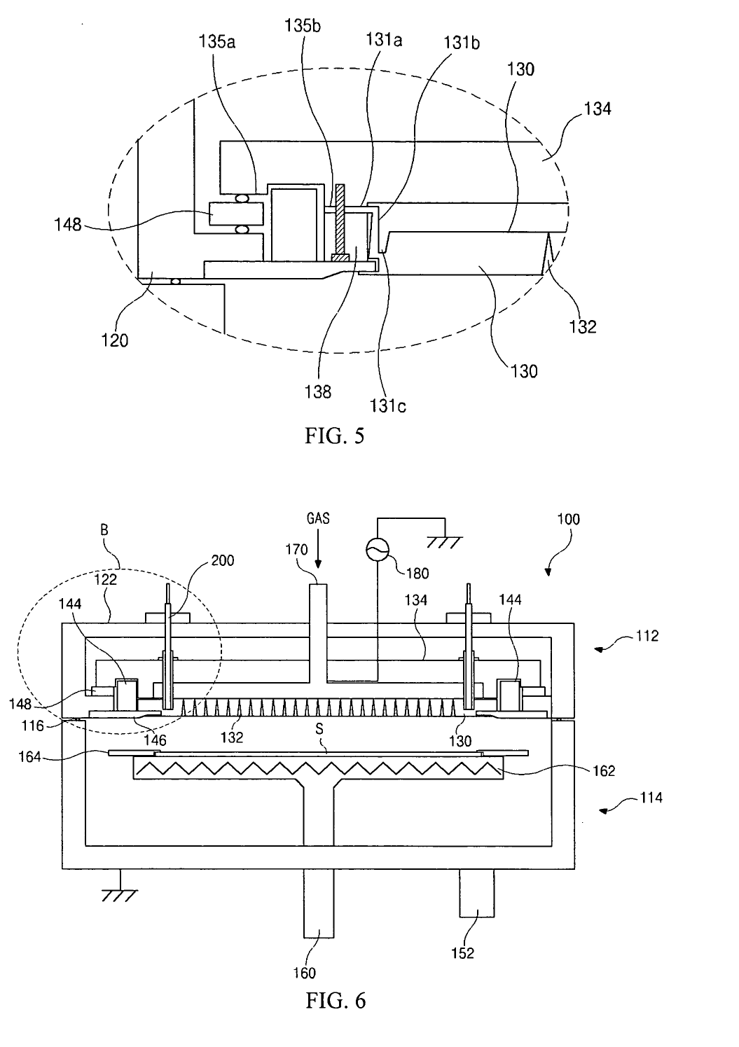

FIG. 5 is a cross-sectional view illustrating an expanded showerhead due to heat conducted from a susceptor according to the first embodiment of the present invention. As shown in FIG. 5, the concavity 131c is formed at the upper surface of the showerhead 130 inside the end portion 131a, which is combined with the connecting part 135b of the backing plate 134. If the showerhead absorbs the heat from the susceptor (not shown), the concavity 131c is expanded to the outside. Therefore, the peripheral portion of the showerhead 130 including the end portion 131a is not transformed or distorted even if there is difference in thermally expanding due to thermal unbalance depending on portions. Accordingly, a deposition rate on the upper surface of the substrate may be uniformly controlled all over the region of the substrate.

Especially, since the vertical portion 131b, which is interposed between the concavity 131c and the end portion 131a of the showerhead 130, is spaced apart from the camping bar 138, the vertical portion 131b may be naturally expanded to the outside. Thus, distortion of the showerhead 130 by thermal stress is effectively controlled, and because the end portion 131a connected to the backing plate 134 is not affected by the expanding force of the showerhead 130, friction around the end portion 131a is largely reduced.

Meanwhile, the thermal energy in the peripheral portion of the showerhead 130 out of the thermal energy radiated from the susceptor (not shown) and the substrate (not shown) to the showerhead 130 is conducted to the backing plate 134 through the end portion 131a of the showerhead 130. In the present invention, because the end portion 131a of the showerhead 130 has a thin plate shape for the center portion of the showerhead 130, a quantity of heat to be conducted to the backing plate 134 is much reduced, and conduction of the heat to the backing plate 134 is effectively stopped. In the present invention, it is possible to decrease the temperature of the backing plate 134 while the heat exchanger is not used, and the PTFE insulator 148 and the O-ring 149 are not damaged.

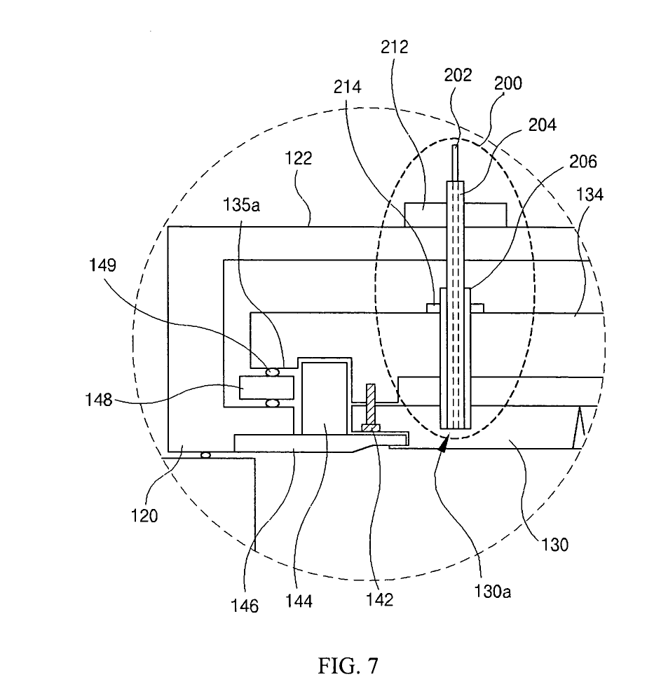

FIG. 6 is a cross-sectional view schematically illustrating a PECVD apparatus according to a second embodiment of the present invention, and FIG. 7 is a view magnifying the part “B” of FIG. 6. Explanation for the same parts as the first embodiment may be omitted.

In FIGS. 6 and 7, since a peripheral portion 131 of a showerhead 130, generally, has a lower temperature than a center portion of the showerhead 130, a sub heater 200 is equipped inside the peripheral portion 131 of the showerhead 130 so that the temperature of the peripheral portion 131 of the showerhead 130 is increased. The sub heater 200 is inserted in a groove 130a that is formed at an upper surface of the showerhead 130 inside the peripheral portion 131 of the showerhead 130, and passes through a backing plate 134 and an upper lid 122 over the showerhead 130 to be connected to a power source (not shown) outside a processing chamber 100. Beneficially, a sub heater clamp block 212 and a sealing bracket 214 are set up on upper surfaces of the upper lid 122 and the backing plate 134 which the sub heater 200 goes through, respectively, to fix the sub heater 200.

The sub heater 200 includes a heating line 202, a first shield 204, and a second shield 206. The heating line 202 is disposed in the first shield 204 and the first shield 204 is surrounded by the second shield 206. That is, the first shield 204 is formed outside the heating line 202 and the second shield 206 is formed outside the first shield 204. The first and second shields 204 and 206 may be divided into two layers.

The first shield 204 is shorter than the heating line 202 and the second shield 206 is shorter than the first shield 204. Thus, the first shield 204 passes through the backing plate 134 and the upper lid 122 from the showerhead 130, and the second shield 206 passes through only the backing plated from the showerhead 130. However, the first shield 204 and the second shield 206 may be varied.

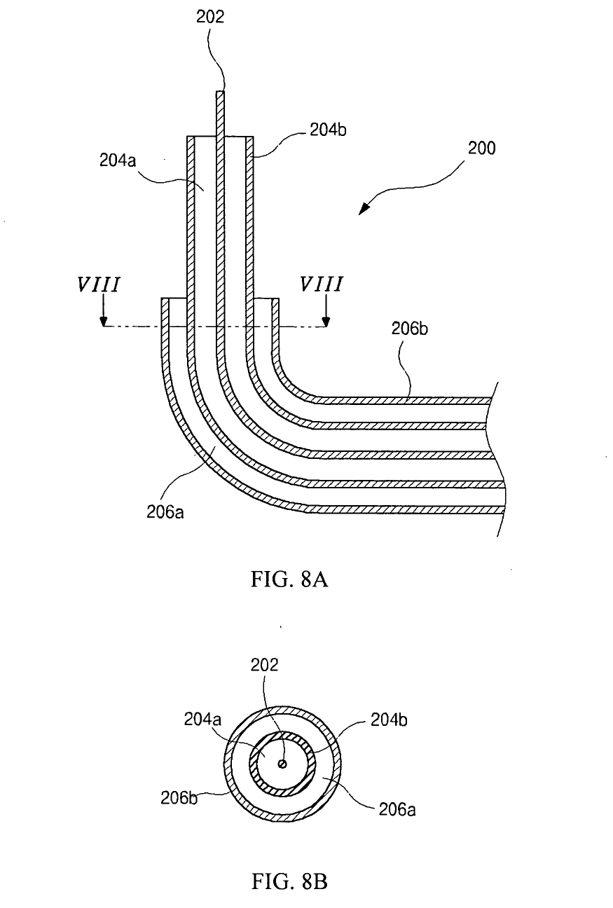

FIG. 8A is a view vertically cutting the sub heater of the present invention and FIG. 8B is a cross-sectional view along the line VIII-VIII of FIG. 8A. In FIGS. 8A and 8B, as state above, the sub heater 200 includes the heating line 202 of the center, the first shield 204 and the second shield 206 sequentially enclosing the heating line 202. The first shield 204 and the second shield 206 are divided into two layers, that is, insulating cores 204a and 206 of the inside and metal sheaths 204b and 206b of the outside. The metal sheaths 204b and 206b may be formed of the same material or may be formed of different materials. Desirably, the metal sheath 204b of the first shield 204 may be formed of stainless steel and the metal sheath 206b of the second shield 206 may be formed of aluminum. The heating line 202 may be formed of nickel or nichrome and the insulating cores 204a and 206a may be formed of magnesium oxide (MgO).

The sub heater 200 is bent, and a lower part of the sub heater 200 is inserted in the showerhead 130 of FIG. 6. That is, the lower part of the sub heater 200 is disposed in the groove 130a of the showerhead 130 of FIG. 7. An upper part of the sub heater 200 passes through the backing plate 134 and the upper lid 122 of FIG. 6.

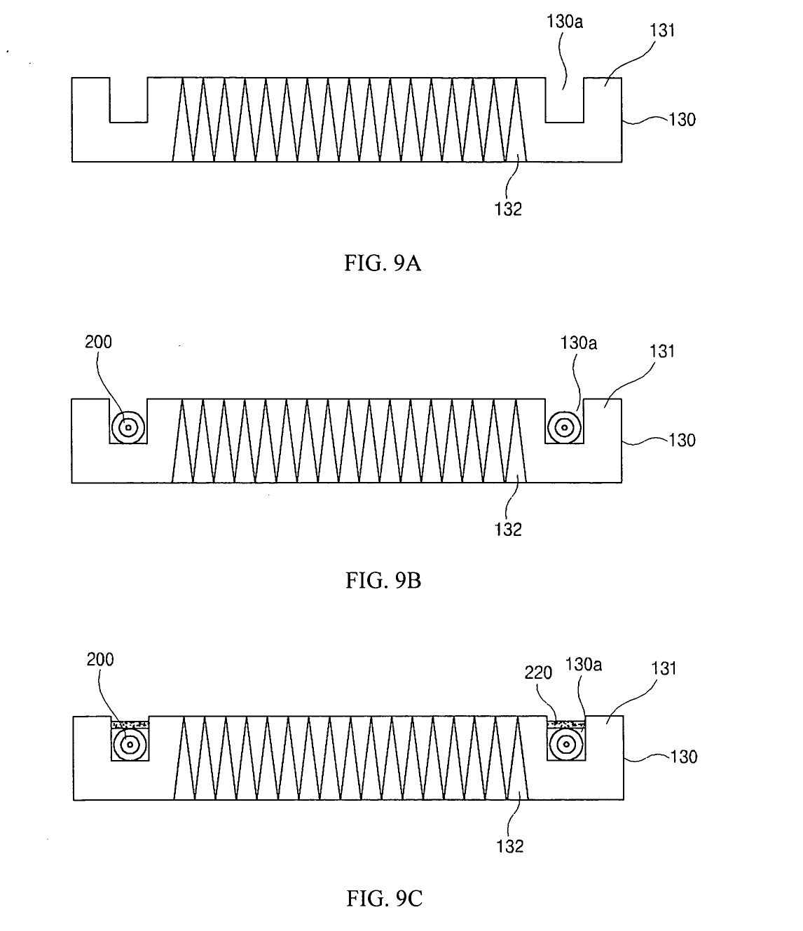

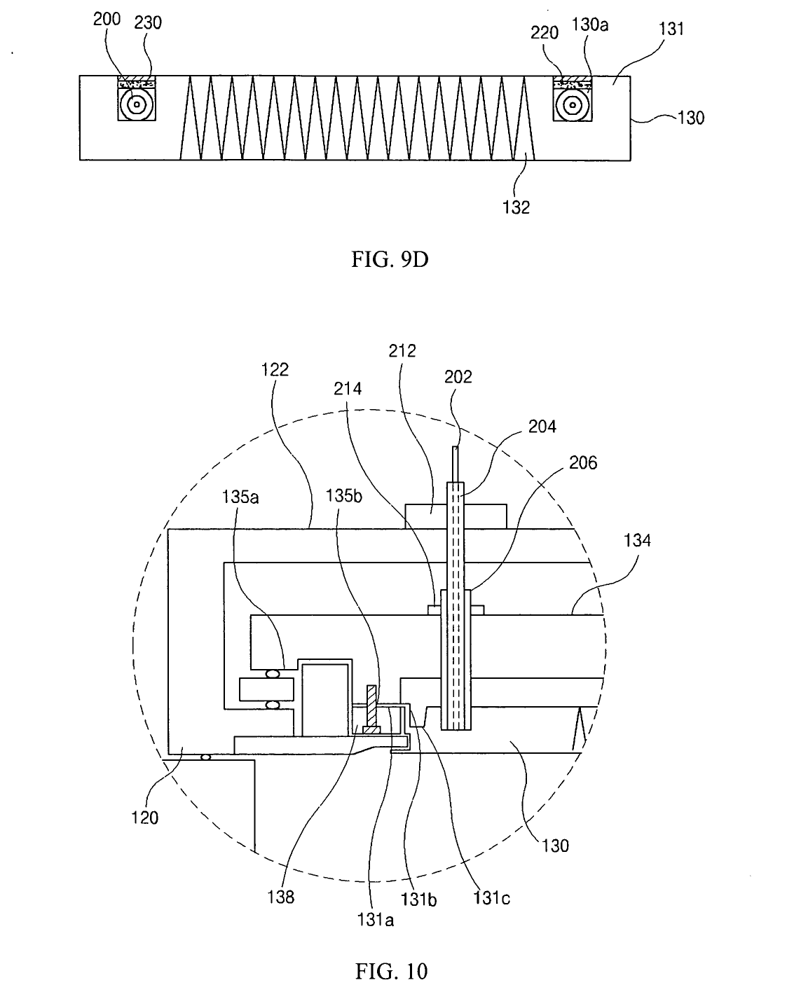

FIGS. 9A to 9D shows a process inserting a sub heater into an upper surface of the showerhead according to the present invention.

In FIG. 9A, a groove 130a is formed at an upper surface of a showerhead 130 inside a peripheral portion 131 in one end thereof. The groove 130a may be formed along the peripheral portion 131 of the showerhead 130, which may have a square shape. Each groove 130a may be formed at both sides of the center portion of the showerhead, facing each other. It is beneficial that the concavities 130 at both sides of the center portion may be spaced apart from each other.

In FIG. 9B, a sub heater 200 is inserted in the groove 130a. If several grooves 130a are formed facing each other with respect to the center portion, several sub heaters 200 may be inserted in grooves 130a, respectively. In this case, the temperature at the peripheral portion 131 of the showerhead 130 may be more uniform.

Next, in FIG. 9C, an aluminum bar 220 is disposed on the sub heater 200 in the groove 130a, and upper and peripheral areas of the groove 130a weld (FIG. 9D, 230). Thus, the sub heater 200 is not exposed over the exterior of the showerhead 130 except for a region where the sub heater 200 passes through the backing plate 134 and the upper lid 122 of FIG. 7.

Accordingly, in the present invention, because the sub heater is equipped on the upper surface inside the peripheral portion of the showerhead, where the showerhead is combined with the backing plate, the temperature of the peripheral portion of the showerhead is increased even if the temperature of the peripheral portion is lowered as compared with the center portion. Thus, formation of particles is prevented and thermal stress of the showerhead is controlled due to substantially equal thermal expansion rates in the center and peripheral portions.

FIG. 10 is a view illustrating a part of a showerhead assembly according to a third embodiment of the present invention. The showerhead assembly of the third embodiment has a periphery, in which a showerhead 130 and a backing plate 134 are combined with each other, different from the second embodiment of FIGS. 6 and 7.

That is, in the third embodiment, a peripheral portion 131a of the showerhead 130 has a thin and long shape, as stated in the first embodiment, and a sub heater 200 is inserted inside of the peripheral portion 131a of the showerhead 130, as mentioned in the second embodiment. Thus, a lowering of the temperature in the peripheral portion 131a as compared with a center portion of the showerhead 130 is compensated, and the peripheral portion 131a of the showerhead 130 is prevented from being distorted and transformed due to different thermal expansion rates.

Accordingly, the showerhead assembly according to the third embodiment can simultaneously solve the problems such as non-uniform deposition of a thin film and formation of contaminants caused by transformation and temperature lowering of the periphery of the showerhead assembly.

The showerhead for the PECVD apparatus of the present invention has the following advantages by controlling thermal unbalance resulting from difference in thermal loss depending on portions of the showerhead.

First, the thermal loss in the peripheral portion of the showerhead, the temperature of which is lowered as compared with the center portion, is compensated, and formation of the powder and particles is suppressed. Therefore, productivity is more increased because of a shorter frequency of the cleaning cycle.

Second, when the showerhead has a large size according to an increasing size of a substrate, although the temperature of the showerhead increases, the showerhead may be expanded into a side direction without distortion and transformation. Thus, a distance between the substrate and the showerhead is uniform in all regions, and a uniform film is formed.

Third, since the end portion of the showerhead having a thin plate shape minimizes heat conduction from the showerhead to the backing plate, the heat exchanger is not necessary. Expenses for the apparatus are cut down, and thermal balance is maintained all over the regions because thermal loss in the peripheral portion of the showerhead is reduced.

Because temperature lopsidedness of the substrate caused by different temperatures depending on the portions of the showerhead and the susceptor may be minimized, unstable temperature at edges of the substrate and inclined thermal expansion of the substrate are restrained. Accordingly, a thin film is uniformly deposited all over the regions of the substrate to obtain a good film.

It will be apparent to those skilled in the art that various modifications and variations can be made in the fabrication and application of the present invention without departing from the spirit or scope of the invention. Thus, it is intended that the present invention cover the modifications and variations of this invention provided they come within the scope of the appended claims and their equivalents.

1. A showerhead assembly of an apparatus for manufacturing a semiconductor device, comprising:
a backing plate having a gas inlet;
a showerhead combined with the backing plate at an end portion thereof, the showerhead having a plurality of holes; and
a sub heater equipped at a peripheral portion of the showerhead.

2. The showerhead assembly according to claim 1, wherein the sub heater passes through the backing plate.

3. The showerhead assembly according to claim 1, wherein the sub heater includes a heating line, a first shield enclosing the heating line, and a second shield surrounding the first sheath.

4. The showerhead assembly according to claim 3, wherein each of the first and second shields are composed of an insulating core and a metal sheath.

5. The showerhead assembly according to claim 4, wherein the insulating core includes magnesium oxide (MgO).

6. The showerhead assembly according to claim 4, wherein the metal sheath of the first shield may be formed of stainless steel.

7. The showerhead assembly according to claim 4, wherein the metal sheath of the second shield may be formed of aluminum.

8. The showerhead assembly according to claim 3, wherein the first shield is shorter than the heating line and the second shield is shorter than the first shield.

9. The showerhead assembly according to claim 1, wherein the end portion of the showerhead is thinner than a portion in which the plurality of holes are formed.

10. The showerhead assembly according to claim 9, wherein the showerhead includes a concavity between the end portion and the plurality of holes.

11. An apparatus for manufacturing a semiconductor device, comprising:
a chamber;
a susceptor in the chamber to hold a substrate thereon;
a showerhead assembly providing gas to the chamber, the showerhead assembly including:
a backing plate having a gas inlet;
a showerhead combined with the backing plate at an end portion thereof, the showerhead having a plurality of holes; and
a sub heater equipped at a peripheral portion of the showerhead; and
a pumping system controlling inner pressure of the chamber.

12. The showerhead assembly according to claim 11, wherein the sub heater passes through the backing plate and a lid of the chamber.

13. The showerhead assembly according to claim 11, wherein the sub heater includes a heating line, a first shield and a second shield, the first shield encloses the heating line, the second shield surrounds the first sheath.

14. The showerhead assembly according to claim 13, wherein each of the first and second shields are composed of an insulating core and a metal sheath.

15. The showerhead assembly according to claim 14, wherein the insulating core includes magnesium oxide (MgO).

16. The showerhead assembly according to claim 14, wherein the metal sheath of the first shield may be formed of stainless steel.

17. The showerhead assembly according to claim 14, wherein the metal sheath of the second shield may be formed of aluminum.

18. The showerhead assembly according to claim 11, wherein the end portion of the showerhead is thinner than a portion in which the plurality of holes are formed.

19. The showerhead assembly according to claim 18, wherein the showerhead includes a concavity between the end portion and the plurality of holes.
